(19) United States
(12) Patent Application Publication
(10) Pub. No.: US 2010/0164063 A1
(43) Pub. Date: Jul. 1, 2010

(54) MIM CAPACITOR AND METHOD FOR FABRICATING THE SAME

(76) Inventor: Jong-Yong Yun, Seocho-gu (KR)

Correspondence Address: SHERR & VAUGHN, PLLC, 620 HERNDON PARKWAY, SUITE 320, HERNDON, VA, 20170, US

(21) Appl. No.: 12/638,184

(22) Filed: Dec. 15, 2009

(30) Foreign Application Priority Data
Dec. 30, 2008 (KR) 10-2008-0137492

(51) Int. Cl. H01L 29/92; H01L 21/02

(52) U.S. Cl. 257/532; 438/381; 257/E29.343; 257/E21.008

(57) ABSTRACT

A MIM capacitor may include a plurality of lower electrodes over a semiconductor substrate. A plurality of insulators may be formed over the lower electrodes, with each insulator having a thickness which is different from the thickness of at least one other insulator among the plurality of insulators. Upper electrodes may be formed over the plurality of insulators. This arrangement permits a plurality of MIM capacitors having differing capacitance values to be formed on a semiconductor substrate, enabling the MIM capacitors to be applied to devices or chips which have various characteristics.

The present application claims priority under 35 U.S.C. 119 to Korean Patent Application No. 10-2008-0137492 (filed on Dec. 30, 2008), which is hereby incorporated by reference in its entirety.

### BACKGROUND

Capacitors are used for storage of charge in a semiconductor device. Basically, a capacitor includes an upper electrode and a lower electrode, which are two conductive plates isolated by an insulator. One type of capacitor uses a PIP (Poly-Insulator-Poly) structure having the insulator between two layers of polysilicon. Another type of capacitor uses a MIM (Metal-Insulator-Metal) structure, including an insulator between metal layers serving as the upper electrode and the lower electrode.

Recently, MIM capacitors have been used, since metal has good electrical properties, and may be required in high frequency devices where characteristic RC delays must be minimized. A related art method for fabricating a MIM capacitor will be described with reference to the attached drawing. FIGS. 1A˜1E illustrate sections showing the steps of a related art method for fabricating an MIM capacitor.

Referring to FIG. 1A, a first metal layer 20 is formed over an oxide film 10. The first metal layer 20 includes a stack of a titanium nitride (TiN) film 22, an aluminum Al film 24, and a titanium nitride (TiN) film 26. As shown in FIG. 1B, an insulator film of, for example, SiN is formed over the first metal layer 20, and TiN is formed over the insulator layer 30 as a second metal layer 40 in succession. As shown in FIG. 1C, a photoresist film mask 50 is formed over the second metal layer 40, which exposes a predetermined region. As shown in FIG. 1C, an exposed portion of the second metal layer 40 is removed completely by dry etching with the photoresist film mask as an etch mask, and a portion of the insulator film 30 is removed by dry etching. As shown in FIG.1D, after removing the photoresist film mask 50, a portion of the insulator film 30 is removed from an upper side of outer sides of the first metal layer 20 by using another photoresist film mask. Then, as shown in FIG. 1D, after etching the first metal layer 20 selectively for forming a metal pattern, an interlayer insulating film 60 is formed to form a shape shown in FIG. 1E.

Capacitance of the related art MIM capacitor depends on a sectional contact area between the metal layer and the SiN. Therefore, all MIM capacitors in a wafer have the same capacitances. Accordingly, structures of MIM capacitors are required which have differing capacitances according to differing purposes of devices.

### SUMMARY

Embodiments relate to device and method for fabricating a semiconductor device and, more particularly, to an MIM (Metal-Insulator-Metal) capacitor and a method for fabricating the same. Embodiments relate to a plurality of MIM capacitors and a method for fabricating the same, which have capacitances different from one another on a semiconductor substrate.

Embodiments relate to an MIM capacitor which may include a plurality of lower electrodes over a semiconductor substrate. A plurality of insulators may be formed over the lower electrodes, with each insulator having a thickness which is different from the thickness of at least one other insulator among the plurality of insulators. Upper electrodes may be formed over the plurality of insulators. This arrangement permits a plurality of MIM capacitors having differing capacitance values to be formed on a semiconductor substrate, enabling the MIM capacitors to be applied to devices or chips which have various characteristics.

Embodiments relate to a method for fabricating an MIM capacitor which forming a first metal layer over a semiconductor substrate; forming a plurality of insulator films over the first metal layer; etching the insulator films such that each insulator has a thickness which is different from the thickness of at least one other insulator among the plurality of insulators; forming a second metal layer over the insulator films; and patterning the first metal layer, the insulator films, and the second metal layer, to form a plurality of MIM capacitors, with each capacitor having a capacitance which is different from the capacitance of at least one other capacitor among the plurality of capacitors, wherein the plurality of capacitors include a lower electrode patterned from the first metal layer, the insulators patterned from the insulator films, and the upper electrode patterned from the second metal layer.

### DRAWINGS

FIGS. 1A˜1E illustrate sections showing the steps of a related art method for fabricating an MIM capacitor.

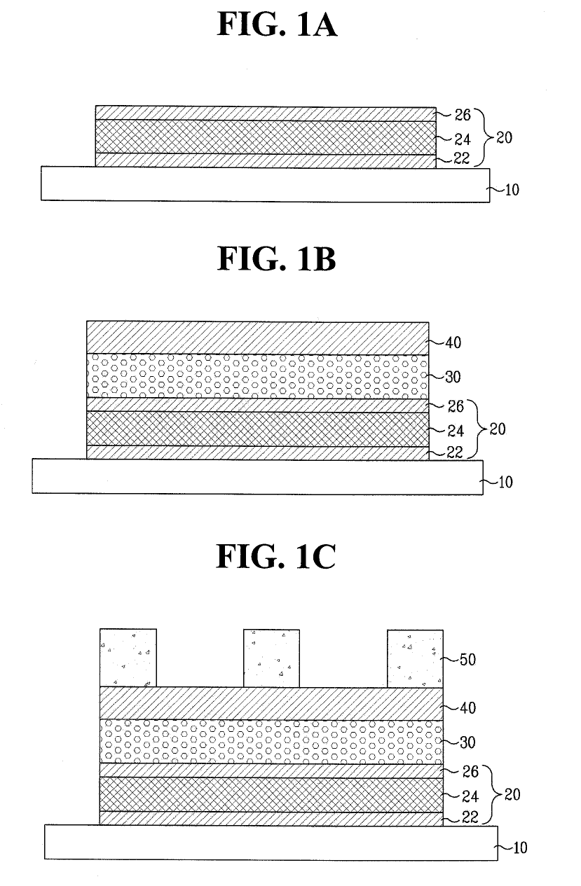

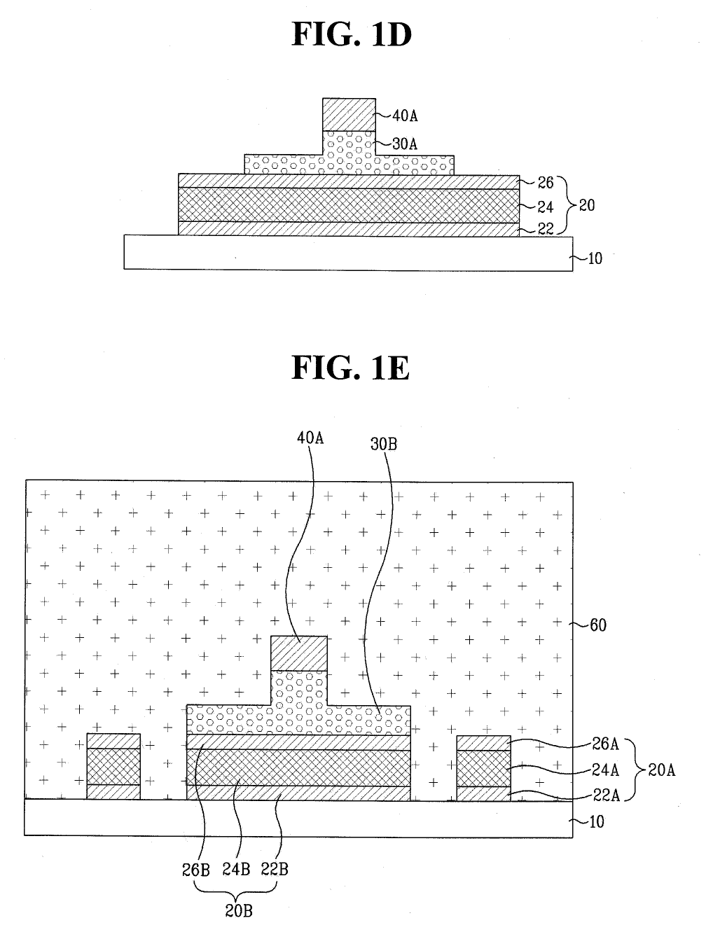

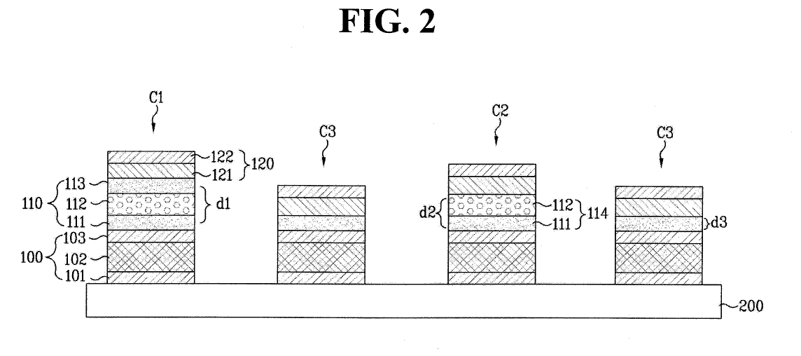

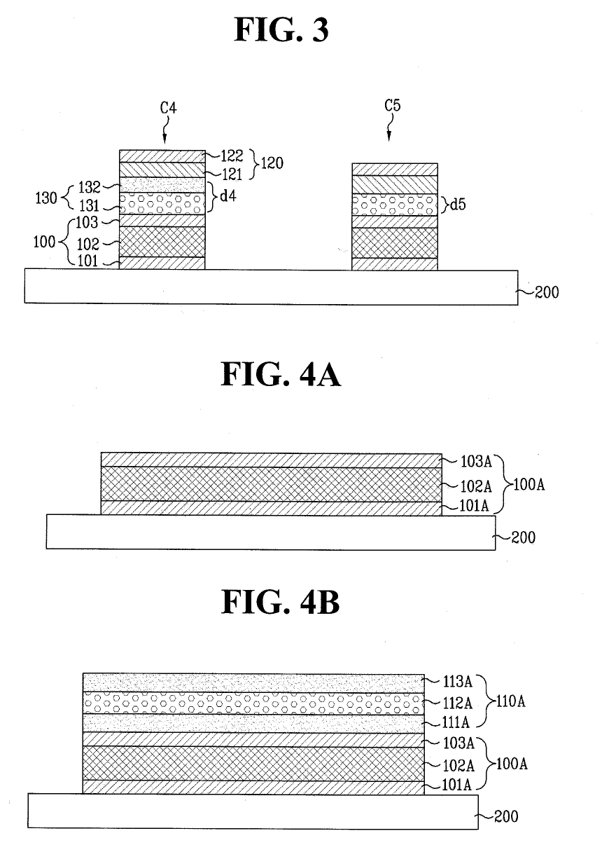

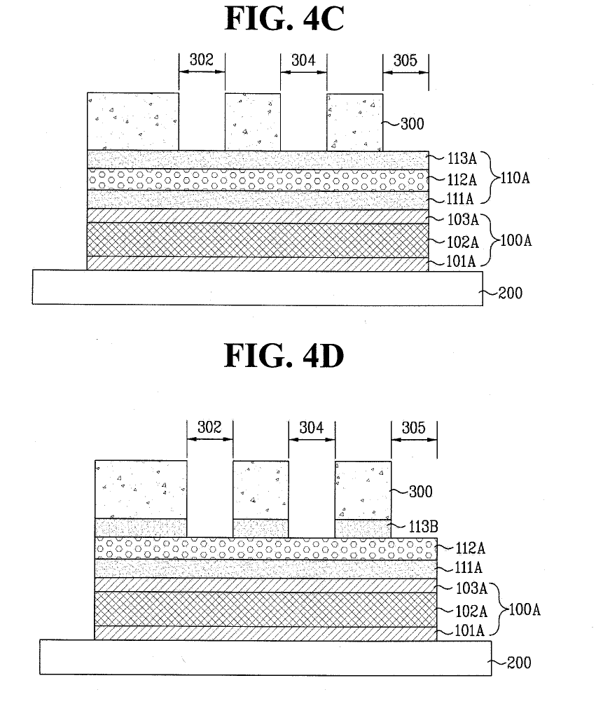

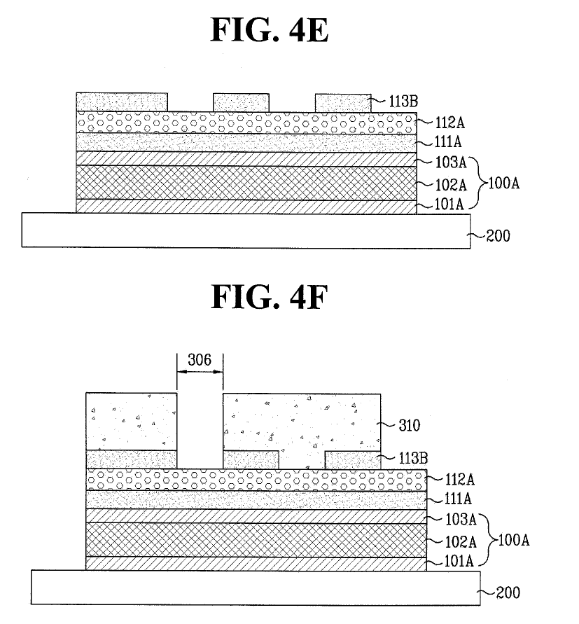

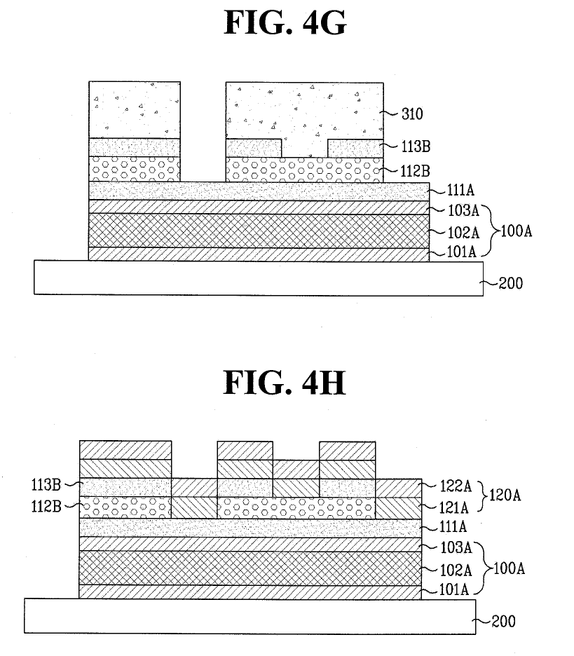

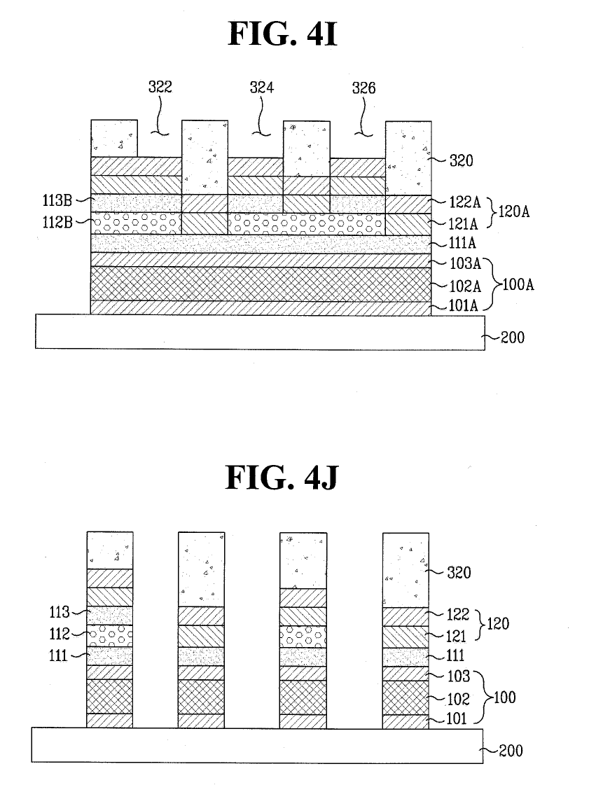

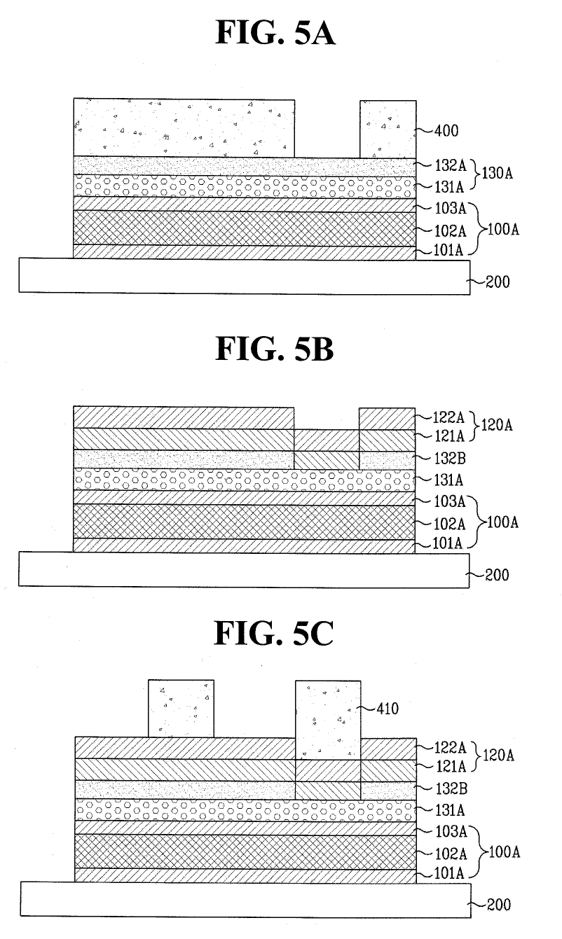

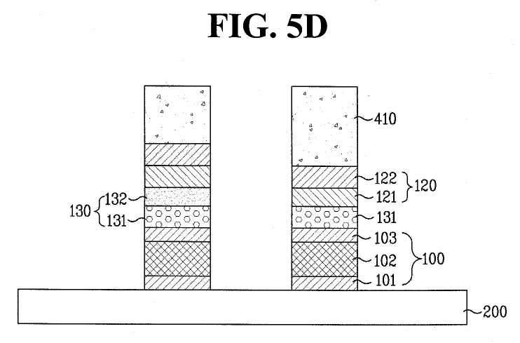

Example FIG. 2 illustrates a section of an MIM capacitor in accordance with embodiments.

Example FIG. 3 illustrates a section of an MIM capacitor in accordance with embodiments.

Example FIGS. 4A˜4J illustrate sections showing the steps of a method for fabricating an MIM capacitor in accordance with embodiments.

Example FIGS. 5A˜5D illustrate sections showing the steps of a method for fabricating an MIM capacitor in accordance with embodiments.

### DESCRIPTION

Example FIG. 2 illustrates a section of an MIM capacitor in accordance with embodiments. Example FIG. 3 illustrates a section of an MIM capacitor in accordance with embodiments. Referring to example FIGS. 2 and 3, MIM (Metal-Insulator-Metal) capacitors C1˜C3 having capacitances different from one another are shown over a semiconductor substrate 200. Reference numeral 200 can be an interlayer insulating film, for example, an oxide film SiO₂, over the semiconductor substrate. For the sake of convenience, the description is made assuming that the reference numeral 200 is the semiconductor substrate, although embodiments are not limited to this.

Lower electrodes 100 of the capacitors C1, C2 and C3 may be formed over the semiconductor substrate 200. Each of the lower electrodes 100 may have a barrier metal layer 101 over the semiconductor substrate 200, an aluminum Al film 102 over the barrier metal layer 101, and a reflection preventive film 103 over the aluminum film 102. The barrier metal layer 102 and the reflection preventive film 103 can be formed of TiN.

Referring to example FIG. 2, insulators having thicknesses d1, d2, and d3 different from one another may be formed over the lower electrodes 100, respectively. In particular, the insulator of the first MIM capacitor C1 may have an ONO structure in which a first oxide film 111, a nitride film 112, and a second oxide film 113 are stacked in succession between the lower electrode 100 and the upper electrode 120, with a thickness of d1. The insulator of the second MIM capacitor C2 may have an ON structure in which the first oxide film 111, and the nitride film 112 are stacked in succession between the lower electrode 100 and the upper electrode 120, with a thickness of d2. The insulator of the third MIM capacitor C3 may have the first oxide film 111 between the lower electrode 100 and the upper electrode 120, with a thickness of d3.

Referring to example FIG. 3, insulators formed over the lower electrodes 100 may have differing thicknesses d4 and d5. In particular, the insulator of the fourth MIM capacitor C4 may have an NO structure in which a nitride film 131, and an oxide film 132 stacked in succession between the lower electrode 100 and the upper electrode 120, with a thickness of d4. The insulator of the fifth MIM capacitor C5 may have the nitride film 131 between the lower electrode 100 and the upper electrode 120, with a thickness of d5.

Upper electrodes 120 may be formed over the insulators. The upper electrode 120 can be formed of titanium Ti 121 and titanium nitride TiN 122. The titanium 121 is over the insulator and the titanium nitride 122 is over the titanium 121.

Referring to example FIG. 2, in order to help understanding the embodiments, the drawing shows the first to third capacitors C1 to C3 with differing thicknesses are all on the semiconductor substrate 200. However, only a subcombination of the three capacitors may be formed over the semiconductor substrate 200, such as only the first capacitor C1 and the second capacitor C2, only the first capacitor C1 and the third capacitor C3, or only the second capacitor C2 and the third capacitor C3.

Since the MIM capacitors C1 to C5 of embodiments may have differing insulator thicknesses d1 to d5 between the lower electrodes 100 and the upper electrodes 120, and differing dielectric constants E of the insulators, the MIM capacitors C1 to C5 may have capacitances different from one another. That is, in general, Equation 1 below expresses capacitance.

$$C = ɛ \frac{A}{d} \qquad Equation 1$$

In Equation 1, d denotes a thickness of the insulator, and A denotes a sectional area of the insulator in contact with a metal layer. As can be shown from equation 1, since thicknesses d1 to d5 of the insulators are different from one another, and dielectric constants c of the insulators are different from one another, the first to fifth MIM capacitors C1 to C5 having different capacitances can be formed on the same semiconductor substrate.

According to the thicknesses d1 to d5 of the insulators and the dielectric constants of the MIM capacitors of embodiments, capacitances of the first to fifth capacitors can be fixed respectively as shown in table 1, below.

TABLE 1

| Thickness of | | Thickness of | Estimated |
|---|---|---|---|
| upper electrode | Kinds of insulator | insulator (Å) | capacitance |
| TiN 1000 Å | Low silane SiN | 640 | 1.02 |
| | SiO₂ | 380 | 1.03 |
| | ONO | 100/300/100 | 1.03 |
| | NO | 450/100 | 1.05 |
| | ON | 100/450 | 1.05 |

Referring to Table 1, the upper electrode 120 may be formed of the titanium nitride TiN 122 only, ONO denotes the insulator of the first capacitor C1, NO denotes the insulator of the fourth capacitor C4, ON denotes the insulator of the second capacitor C2, SiO₂ denotes the insulator of the third capacitor C3, and low silane SiN denotes the insulator of the fifth capacitor C5. The unit measure for the estimated capacitance is pF/μm².

A method for fabricating an MIM capacitor in accordance with embodiments will be described with reference to the attached drawings. Example FIGS. 4A˜4J illustrate sections showing the steps of a method for fabricating an MIM capacitor in accordance with embodiments. The MIM capacitors C1 to C3 can be fabricated by a method shown in example FIGS. 4A to 4J, respectively.

Referring to example FIG. 4A, a first metal layer 100A may be formed over a semiconductor substrate 200. According to embodiments, the first metal layer 100A can be formed as follows. A barrier metal layer 101A may be formed over the semiconductor substrate 200. An aluminum Al film 102A may be formed over the barrier metal layer 101A. Then, a reflection preventive film 103A may be formed over the aluminum film 102A. The barrier metal layer 101A and the reflection preventive film 103A can be formed of titanium nitride TiN.

Referring to example FIG. 4B, a plurality of insulator films 110A may be formed over the first metal layer 100A. The plurality of insulator films 110A may include at least two of a first oxide film 111A, a nitride film 112A, and a second oxide film 113A. That is, the plurality of insulator films 110A may only include the first oxide film 111A, and the nitride film 112A. For convenience's sake, all of the first oxide film 111A, the nitride film 112A, and the second oxide film 113A are illustrated as formed over the first metal layer 100A as the insulator films. That is, the first oxide film 111A is formed over the first metal layer 100A. The nitride film 112A may be formed over the first oxide film 111A. The second oxide film 113A may be formed over the nitride film 112A.

Referring to example FIGS. 4C to 4G, the insulator films 110A may be etched such that the insulator films have a plurality of thicknesses different from one another. According to embodiments, the insulator films 110A may be etched as follows.

Referring to example FIG. 4C, a first photoresist film mask 300 may be formed over the plurality of insulator films 110A, which exposes first regions 302, 304, and 305. Referring to example FIG. 4D, the first regions 302, 304, and 305 of some of the insulator films 111A, 112A, and 113A, for example, the second oxide film 113A, may be dry etched by using the first photoresist film mask 300. Referring to example FIG. 4E, the first photoresist film pattern 300 may be removed.

Then, referring to example FIG. 4F, after removing the first photoresist film pattern 300, a second photoresist film mask 310 may be formed, which exposes a second region 306 which exposes an upper side of etched resultant materials 112A and 113B. The second region 306 may be formed over the same region as the first region 302, but may be spaced from the first regions 304 and 305.

Referring to example FIG. 4G, the second region 306 of some of the insulator films 111A, 112A, and the 113B, for an example, the nitride film 112A, is etched. Referring to example FIG. 4H, the second photoresist film pattern 310 may be removed. Then, a second metal layer 120A may be formed over the insulator films having a plurality of thicknesses different from one another. For example, titanium 121A and titanium nitride TiN 122A may be sputtered over an upper side of the insulator films to form the second metal layer 120A. Alternatively, only the titanium nitride TiN 122A may be sputtered over an upper side of the insulator films to form the second metal layer 120A.

Referring to example FIGS. 41 and 4J, the first metal layer 100A, the insulator films with a plurality of differing thicknesses, and the second metal layer 120A are patterned, to form a plurality of MIM capacitors C1 to C3 having varying capacitances. That is, referring to example FIG. 41, a third photoresist film mask 320 may be formed over the first metal layer 100A, the insulator films, and the second metal layer 120A. The third photoresist film mask 320 may be patterned to expose third regions 322, 324, and 326 where none of the first to third capacitors C1 to C3 are to be formed. As shown in example FIG. 4J, the second metal layer 120A may be etched by using the third photoresist film mask as an etch mask, to form an upper electrode 120, and the insulator films having a plurality of thicknesses different from one another are etched, to form insulators, and the first metal layer 100A is etched, to form a lower electrode 100.

Thereafter, referring to example FIG. 2, the third photoresist film mask 320 may be removed to complete the process of forming first to third capacitors C1 to C3. At the end, each of the plurality of capacitors C1 to C3 has a lower electrode 100 patterned from the first metal layer 100A, insulators patterned from the insulator films 110A, and an upper electrode 120 patterned from the second metal layer 120A.

In embodiments, different from example FIG. 2, only the first and second capacitors C1 and C2 may be formed, only the first and third capacitors C1 and C3 may be formed, or only the second and third capacitors C2 and C3 may be formed. To do this, the only required change is to the first and second regions exposed by the first and second photoresist film masks 300 and 310 in example FIGS. 4C and 4F.

For example, when it is intended to form only the first and third capacitors C1 and C2, the first photoresist film mask 300 in example FIG. 4C may be formed to expose, not the first region 302 and 305, but the first region 304 only. Then, steps shown in example FIGS. 4F and 4G may be omitted. The second metal layer 120A may be formed as shown in example FIG. 4H on resultant materials shown in example FIG. 4E. Then, dry etching may be performed as shown in example FIG. 4j using the third photoresist film mask 320 shown in example FIG. 4I. In this case, two first capacitors C1 and two second capacitors C2 are formed. That is, the third capacitor C3 on a left side of the second capacitor C2 has insulators identical to the first capacitor C1 and the third capacitor C3 on a right side of the second capacitor C2 has insulators identical to the second capacitor C2.

A method for fabricating an MIM capacitor in accordance with embodiments will be described with reference to the attached drawings. Example FIGS. 5A˜5D illustrate sections showing the steps of a method for fabricating an MIM capacitor in accordance with embodiments. The MIM capacitors C4 and C5 in example FIG. 3 may be fabricated by the method in example FIGS. 5A to 5D.

Referring to example FIG. 5A, a first metal layer 100A may be formed over a semiconductor substrate 200. Since the formation of the first metal layer 100A may be identical to example FIG. 4A, a detailed description will be omitted. A plurality of insulator films 130A may be formed over the first metal layer 100A. The plurality of insulator films 130A may include the nitride film 131A and the oxide film 132A. First, the nitride film 131A may be formed over the first metal layer 100A. Then, the oxide film 132A may be foiined over the nitride film 131A.

Referring to example FIG. 5B, the insulator films 130A may be etched such that the insulators have a plurality of thicknesses different from one another. In particular, as shown in example FIG. 5A, a photoresist film mask 400 may be formed over the plurality of insulator films 130A. As shown in example FIG. 5B, some insulator film 132A of the insulator films 131A and 132A may be dry etched by using the photoresist film mask 400. Then, the photoresist film pattern 400 may be removed.

Referring to example FIG. 5C, after removing the photoresist film pattern 400, a second metal layer 120A may be formed over the insulator films having a plurality of thicknesses different form one another. Since the formation of the second metal layer 120A may be identical to example FIG. 4H, a detailed description will be omitted.

Referring to example FIGS. 5C and 5D, the insulator films and the second metal layer 120A may be patterned, to form a plurality of MIM capacitors C4 and C5 having insulators with differing thicknesses. That is, referring to example FIG. 5C, the photoresist film mask 410 may be formed over the second metal layer 120A, which exposes none of the regions where the fourth and fifth capacitors C4 and C5 are to be formed. As shown in example FIG. 5D, the second metal layer 120A may be etched by using the photoresist film mask as an etch mask, to form an upper electrode 120. The insulator films may be etched to form insulators having thicknesses different form one another. The first metal layer 100A is etched to form a lower electrode 100. Then, as shown in example FIG. 3, upon removal of the photoresist film 410, the fourth and fifth capacitors C4 and C5 are completed.

Eventually, each of the plurality of capacitors C4 and C5 has a lower electrode 100 patterned from the first metal layer 100A, the insulators patterned from the insulator films 110A, and the upper electrode 120 patterned from the second metal layer 120A.

As has been described, the MIM (Metal-Insulator-Metal) capacitor and the method for fabricating the same may have the following advantages. The plurality of MIM capacitors having differing capacitance values on the same wafer, i.e., semiconductor substrate, permits application of devices or chips having different characteristics.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a plurality of lower electrodes over a semiconductor substrate;
a plurality of insulators formed over the lower electrodes, wherein each insulator has a thickness which is different from the thickness of at least one other insulator among the plurality of insulators; and
upper electrodes formed over the plurality of insulators.

2. The apparatus of claim 1, wherein the plurality of lower electrodes include:
a barrier metal layer over the semiconductor substrate;
an aluminum film over the barrier metal layer; and
a reflection preventive film over the aluminum film.

3. The apparatus of claim 1, wherein a first insulator among the plurality of insulators includes an oxide film between the lower electrode and the upper electrode, and a second insulator among the plurality of insulators includes an oxide film and a nitride film stacked in succession between the lower electrode and the upper electrode.

4. The apparatus of claim 1, wherein a first insulator among the plurality of insulators includes a first oxide film between the lower electrode and the upper electrode, and a second insulator among the plurality of insulators includes a first oxide film, a nitride film and a second oxide film stacked in succession between the lower electrode and the upper electrode.

5. The apparatus of claim 1, wherein a first insulator among the plurality of insulators includes a first oxide film and a nitride film stacked in succession between the lower electrode and the upper electrode, and a second insulator among the plurality of insulators includes a first oxide film, a nitride film and a second oxide film stacked in succession between the lower electrode and the upper electrode.

6. The apparatus of claim 1, wherein a first insulator among the plurality of insulators includes a first oxide film between the lower electrode and the upper electrode, a second insulator among the plurality of insulators includes a first oxide film and a nitride film stacked in succession between the lower electrode and the upper electrode, and a third insulator among the plurality of insulators includes a first oxide film, a nitride film and a second oxide film stacked in succession between the lower electrode and the upper electrode.

7. The apparatus of claim 1, wherein a first insulator among the plurality of insulators includes a nitride film between the lower electrode and the upper electrode, and a second insulator among the plurality of insulators includes a nitride film and an oxide film tacked in succession between the lower electrode and the upper electrode.

8. A method comprising:
forming a first metal layer over a semiconductor substrate;
forming a plurality of insulator films over the first metal layer;
etching the insulator films such that each insulator has a thickness which is different from the thickness of at least one other insulator among the plurality of insulators;
forming a second metal layer over the insulator films; and
patterning the first metal layer, the insulator films, and the second metal layer, to form a plurality of MIM capacitors, with each capacitor having a capacitance which is different from the capacitance of at least one other capacitor among the plurality of capacitors
wherein the plurality of capacitors include a lower electrode patterned from the first metal layer, the insulators patterned from the insulator films, and the upper electrode patterned from the second metal layer.

9. The method of claim 8, wherein forming a first metal layer includes:
forming a barrier metal layer over the semiconductor substrate,
forming an aluminum film over the barrier metal layer, and
forming a reflection preventive film over the aluminum film.

10. The method of claim 9, wherein the barrier metal layer and the reflection preventive film are formed of titanium nitride.

11. The method of claim 8, wherein forming a plurality of insulator films includes:
forming a nitride film over the first metal layer; and
forming an oxide film over the nitride film.

12. The method of claim 8, wherein forming a plurality of insulator films includes:
forming a first oxide film over the first metal layer;
forming a nitride film over the first oxide film; and
forming a second oxide film over the nitride film.

13. The method of claim 8, wherein forming a plurality of insulator films includes:
forming an oxide film over the first metal layer; and
forming a nitride film over the oxide film.

14. The method of claim 8, wherein etching the insulator films includes:
forming a first photoresist film mask over the plurality of insulator films, the first photoresist film exposing a first region;
etching the first region of some of the insulator films using the first photoresist mask; and
removing the first photoresist film pattern.

15. The method of claim 14, wherein etching the insulator films includes:
forming a second photoresist film mask over resultant etched materials, the second photoresist film mask exposing a second region, after removing the first photoresist film pattern;
etching the second region of some of the insulator films by using the second photoresist film mask; and
removing the second photoresist film pattern.

16. The method of claim 15, wherein the first region and the second region are the same region.

17. The method of claim 15, wherein the first region and the second region are spaced apart from each other.

18. The method of claim 8, wherein forming a second metal layer includes depositing titanium nitride TiN over the insulator films.

19. The method of claim 8, wherein forming a second metal layer includes:
depositing titanium over the insulator films; and
depositing titanium nitride TiN over the titanium.

20. The method of claim 8, including forming the insulator films of the plurality of capacitors to have differing thicknesses.
